(19) United States
(12) Patent Application Publication
(10) Pub. No.: US 2010/0189880 A1
(43) Pub. Date: Jul. 29, 2010

(54) Method and Apparatus for Extruding a Liquid Onto a Substrate and Inspecting the Same

(75) Inventors: Greg Gibson, Dallas, TX (US); Scott Snodgrass, Rowlett, TX (US)

Correspondence Address: STORM LLP, BANK OF AMERICA PLAZA, 901 MAIN STREET, SUITE 7100, DALLAS, TX, 75202, US

(73) Assignee: FAS HOLDINGS GROUP, LLC, Dallas, TX (US)

(21) Appl. No.: 12/595,452

(22) PCT Filed: Apr. 10, 2008
(86) PCT No.: PCT/US08/59919

§ 371 Date: Mar. 29, 2010

Related U.S. Application Data
(60) Provisional application No. 60/911,017, filed on Apr. 10, 2007.

(51) Int. Cl. C23C 14/54; B05C 11/02

(52) U.S. Cl. 427/10; 118/665

(57) ABSTRACT

An extrusion and inspection apparatus is provided. Specifically, the apparatus includes a generally horizontal surface adapted to support a substrate and a coating die that extrudes fluid onto the substrate. A shuttle having a bridge with the coating die mounted thereon moves the coating die generally parallel to the substrate. In addition to lateral motion parallel to the substrate, the apparatus includes a gauging member that positions the die to at least one predetermined position above the substrate. A light source secured to the bridge is also employed to illuminate the substrate before and/or after coating. The apparatus also includes an imager secured to the bridge where the imager obtains images of the substrate during illumination.

### CROSS-REFERENCE TO RELATED APPLICATIONS

This application claims priority to U.S. Patent Application Ser. No. 60/911,017, filed on Apr. 10, 2007, and which is hereby incorporated by reference for all purposes.

### TECHNICAL FIELD

The invention relates generally to methods and apparatus for depositing material onto a substrate.

### BACKGROUND OF THE INVENTION

In many applications today, extruders are employed to provide films onto substrates. Some of these applications include the production of Flat Panel Displays (FPD) and semiconductors. Additionally, for the purposes of quality assurance (among other purposes), inspection of the film on the substrate is employed. Conventionally, separate machines are employed to perform the functions of extruding a film and inspecting the film. Some examples of such conventional apparatuses are U.S. Pat. Nos. 5,853,812; 4,938,994; and 6,309,692. Therefore, there is a need for a method and apparatus that can perform both the functions of extrusion and inspection.

### SUMMARY

The present invention, accordingly, provides an extrusion and inspection apparatus in accordance with a preferred embodiment of the present invention. Specifically, the apparatus includes a generally horizontal surface adapted to support a substrate and a coating die that extrudes fluid onto the substrate. A shuttle having a bridge with the coating die mounted thereon moves the coating die generally parallel to the substrate. In addition to lateral motion parallel to the substrate, the apparatus includes a gauging member that positions the die to at least one predetermined position above the substrate. A light source secured to the bridge is also employed to illuminate the substrate before and/or after coating. The apparatus also includes an imager secured to the bridge where the imager obtains images of the substrate during illumination.

In accordance with a preferred embodiment of the present invention, a method of extruding and inspecting is also provided. A substrate is illuminated prior to coating. Images of the substrate are obtained during illumination prior to coating. A bridge is adjusted to a predetermined height above the substrate. The bridge is moved in a plane that is generally parallel to the substrate. A liquid is extruded onto the substrate. The substrate and extrudate are illuminated. Images of the substrate and extrudate are obtained, and the substrate and extrudate are evaluated to determine the positions of errors.

Additionally, in accordance with a preferred embodiment of the present invention, a system for coating a substrate with a material is provided. The system includes a movable shuttle, a dispenser carried by the shuttle, a chuck for holding the substrate, and an imaging apparatus carried by the shuttle and arranged to obtain image characteristics of the substrate before and/or after coating. The dispenser dispenses the material onto the substrate, and the substrate remains in a fixed position relative to the shuttle.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is an isometric view of an extrusion and inspection apparatus in accordance with a preferred embodiment of the present invention; and

FIG. 2 is an isometric view of the inspection camera system in accordance with a preferred embodiment of the present invention.

### DETAILED DESCRIPTION

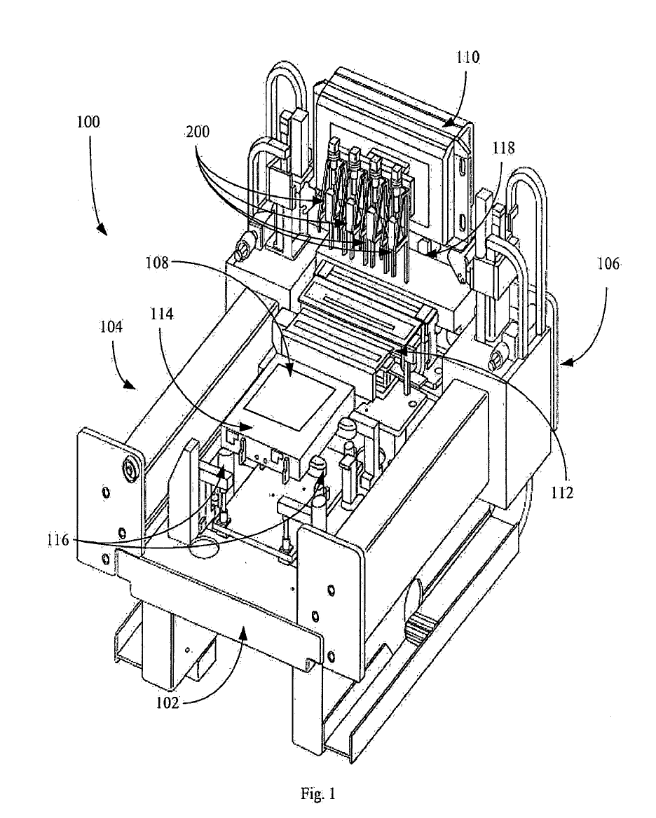

Referring to FIG. 1 of the drawings, the reference numeral 100 generally depicts the coating apparatus 100 according to a preferred embodiment of the present invention. A base 102 with a rail system 104 mounted thereon forms a foundation along which the shuttle or transport system 106 travels for cleaning and priming of the dispensing head or die 118, and coating operations of the substrate 108. Specifically, the dispensing head or die 118 and a gauging member (not shown) are mounted to the bridge 110, which extends generally perpendicular between the rails of the rail system 104.

Also, a chuck 114 is secured to the base 102 through chuck holders 116. Chuck 114 provides support and positioning of substrate 108. Preferably, the chuck 114 employs a vacuum to secure or “hold down” the substrate 108 in a generally fixed horizontal position relative to the shuttle 106 during operation of the coating apparatus 100. In a preferred embodiment of this invention, chuck holder 116 comprises a structure which will preferably support the chuck 114 principally at a plurality of points around the periphery of the chuck 114. Correspondingly, the chuck 114 is ground so that it is as flat as possible as supported. Alternatively, the chuck 114 can be formed so as to selectively deform to compensate for deformation in the shuttle 106 and head 118.

In particular, a gauging member (not shown) can be implemented on the shuttle 106 to fine tune the gap between the dispenser or dispensing head 118 and the substrate 108 in real time during the coating operation. A height sensor as part of the gauging member (not shown) is appropriately zeroed while the head 118 is at the correct height, and a correction signal is subsequently generated whenever the height deviates above or below the preset level. The height sensor typically comprises one or more non-contact laser sensors that measure the relative height above the substrate 108, which constitutes an indirect feedback control. Alternatively, a physically contacting probe or rod can be used to supply direct feedback control

These feedback controls are used by a control system to adjust the height of the dispensing head 118 and the bridge 110. The control system for the gauging member is generally comprised of computer hardware and software that convert the feedback signal into information suitable to drive the position motor(s) to restore the dispensing head to the proper height. This process of height self-correction typically begins at the start of the coating process and continues throughout the coating process. However, it is preferable to make this adjustment only at the start of the coating process (to compensate for various thicknesses of different substrates), and to not make adjustments during the coating.

In operation, the dispensing head 118 moves above the chuck 114 supporting substrate 108. During motion of the dispensing head 118, its height can be adjusted by the gauging member (not shown). The dispensing head 118 is preferably a linear extrusion head attached to fluid manifold preferably containing a bead forming orifice substantially as described in U.S. Pat. No. 4,696,885, titled “METHOD OF FORMING A LARGE SURFACE AREA INTEGRATED CIRCUIT.” Although a stationary substrate 108 and movable shuttle 106 is preferred because it occupies less space, the head 118 and camera systems 200 could be maintained stationary while the substrate 108 is moved relative thereto.

The travel of the shuttle 106 preferably will be at least long enough to permit the dispensing head 118 to coat the largest substrate to be placed on the apparatus 100 and to clear the substrate 108 by a sufficient distance to permit the substrate 108 to be removed by external personnel or machinery. Although, this range may be reduced by providing for some movement of the substrate 108 during coating. The travel of the shuttle 106 will preferably also be long enough so that in addition to clearing the substrate 108, the shuttle 106 will be able to gain access to utility station 112.

To reduce the system footprint, and to improve coating performance, particularly on the leading edge of a substrate 108 (starting point for the coating operation), substrate 108 is located as close as possible to utility station 112. Preferably, the shuttle 106 carries the bridge 110 and the dispensing head 118 to the utility station 112 for head cleaning and for priming of the bead either before or during the loading of the substrate 108. The shuttle 106 then carries the bridge 110 and the dispensing head 118 to the near edge of the substrate 108 (the side closest to the station 112) so that coating of the substrate 108 may begin. The shuttle 106 then carries the dispensing head 118 across the substrate at a carefully monitored and predetermined rate, preferably under computer control, while the dispensing head 118 dispenses coating material at a controlled rate onto the substrate 108. Once the shuttle 106 has traveled to a point where the dispensing head 118 has coated the entire substrate 108 or that portion to be coated, fluid flow to the dispensing head 118 is discontinued.

It should also be appreciated that there is no limitation that the present invention coat the entire surface of the substrate 108. For example, the motion of the head 118 may be stopped at some point prior to fully coating a substrate 108 where only a portion of the substrate 108 is desired to be coated. Additionally, or alternatively, the length of the head 118 may be such that only a portion of the substrate 108 is coated even with full travel of the head 118.

In addition to extruding a liquid onto the substrate 108, the apparatus 100 also inspects the substrate 108. During the manufacture of Thin Film Transistor (TFT) screens, Liquid Crystal Displays (LCDs), and other such devices, it is important to identify processing defects. To accomplish this, a number of camera systems 200 are employed. Each of these systems 200 are secured to or mounted on the bridge 110, so that, upon completion of the extrusion process(es), inspection of the substrate 108 can commence. By incorporating the camera systems 200 into the apparatus 100, the number of machines used to process or otherwise manufacture the finished product, such as an LCD, is reduced. This reduction in the total number of machines necessary to produce such products results in a reduction in the overall footprint of the equipment, and in a reduction of the total investment for the manufacturing line.

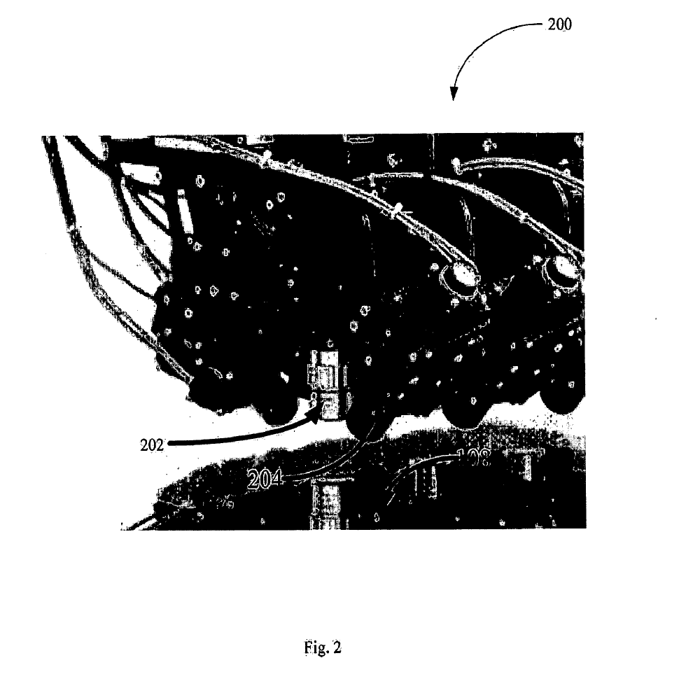

Now turning to FIG. 2 of the drawings, the camera systems 200 can be seen in greater detail. Each of the camera systems 200, which are secured or mounted to the bridge 100 include a light source 202. Typically, this light source is a solid state light source, such as a Light Emitting Diode (LED) or diode laser. The light source 202 illuminates the substrate 108 and the extrudate located on the substrate 108. Operating in conjunction with the light source 202 are a number of imagers or cameras 204, which are preferably high resolution Charged Coupled Devices (CCDs), that detect radiation reflected off of the substrate 108 and/or the extrudate. Incorporated with these cameras 204 are optical elements, such as diffraction limited optical elements, to produce clearer images and reduce optical errors. Typically, these systems 200 are adapted to detect particles on the extrudate or surface of about 10 μm in size.

Now turning back to FIG. 1, in operation, prior to and upon completion of the extrusion process(es), the bridge 110 passes back over the substrate 108 and the extrudate located on the substrate 108. Light source(s) 202 of the respective systems 200 illuminate the substrate 108 and/or extrudate. Light or radiation reflected off of the substrate 108 and/or extrudate is captured by the respective cameras 204 and are relayed to a data capture system (not shown) which interprets the results and reports errors in the extrusion processing or in the substrate 108. Additionally, the systems 200 can also be employed to examine substrate 108 without any particular coating process.

Having thus described the present invention by reference to certain of its preferred embodiments, it is noted that the embodiments disclosed are illustrative rather than limiting in nature and that a wide range of variations, modifications, changes, and substitutions are contemplated in the foregoing disclosure and, in some instances, some features of the present invention may be employed without a corresponding use of the other features. Many such variations and modifications may be considered obvious and desirable by those skilled in the art based upon a review of the foregoing description of preferred embodiments. Accordingly, it is appropriate that the appended claims be construed broadly and in a manner consistent with the scope of the invention.

1. An extrusion and inspection apparatus, comprising:
a generally horizontal surface adapted to support a substrate;
a coating die that extrudes fluid onto the substrate;
a shuttle having a bridge with the coating die mounted thereon, the coating die being movable generally parallel to the substrate;
a gauging member that positions the die to at least one predetermined position above the substrate;
a light source secured to the bridge, the light source being adapted to illuminate the substrate before and after coating; and
an imager secured to the bridge, the imager obtaining images of the substrate during illumination.

2. A method of extruding and inspecting, comprising:
illuminating a substrate prior to coating;
obtaining images of the substrate during illumination prior to coating;
adjusting a bridge to a predetermined height above the substrate;
moving the bridge in a plane that is generally parallel to the substrate;
extruding a liquid onto the substrate;
illuminating the substrate and extrudate;
obtaining images of the substrate and extrudate; and
evaluating the substrate and extrudate to determine the positions of errors.

3. A method of extruding and inspecting, comprising:
adjusting a bridge to a predetermined height above a substrate;
moving the bridge in a plane that is generally parallel to the substrate;
extruding a liquid onto the substrate;
illuminating the substrate and extrudate;
obtaining images of the substrate and extrudate; and
evaluating the substrate and extrudate to determine the positions of errors.

4. A method of extruding and inspecting, comprising:
illuminating a substrate prior to coating;
obtaining images of the substrate during illumination prior to coating; and
evaluating the substrate to determine the positions of errors.

5. A system for coating a substrate with a material, the system comprising:
a movable shuttle;
a dispenser carried by the shuttle, the dispenser for dispensing the material onto the substrate;
a chuck for holding the substrate, wherein the substrate remains in a fixed position relative to the shuttle; and
an imaging apparatus carried by the shuttle and adapted to obtain image characteristics of the substrate before and after coating.
